(19) United States
(12) Patent Application Publication
(10) Pub. No.: US 2009/0146288 A1
(43) Pub. Date: Jun. 11, 2009

(54) SEMICONDUCTOR DEVICE AND METHOD OF MANUFACTURING THE SAME

(75) Inventor: Mitsuhiro Mishima, Kadoma-shi (JP)

Correspondence Address: STEPTOE & JOHNSON LLP, 1330 CONNECTICUT AVE., NW, WASHINGTON, DC, 20036, US

(73) Assignee: Panasonic Corporation, Kadoma-shi (JP)

(21) Appl. No.: 12/327,015

(22) Filed: Dec. 3, 2008

(30) Foreign Application Priority Data
Dec. 7, 2007 (JP) 2007-316473

(51) Int. Cl. H01L 23/04; H01L 21/02

(52) U.S. Cl. 257/698; 438/26; 257/E21.002; 257/E23.011

(57) ABSTRACT

A semiconductor element 22 is mounted on a stem 24 where a flat surface serving as the mounting part of the semiconductor element 22 is provided on a part of a cylindrical part, and the stem 24 is inserted and hermetically sealed into a cap 25 such that the cylindrical part comes into contact with the cap 25. The size of the cylindrical shape of the stem 24 is minimized as a width of the mounting part so large as to mount the semiconductor element 22. Thus it is possible to achieve high heat dissipation and reduce the thickness of a semiconductor device 100, and further reduce the sizes of an optical pickup device and an optical disk drive unit.

### FIELD OF THE INVENTION

The present invention relates to a semiconductor device and a method of manufacturing the same.

### BACKGROUND OF THE INVENTION

In recent years, large-capacity rewritable optical disks loaded in DVD recorders, personal computers, and blue ray recorders have rapidly become widespread. Particularly, thinner optical disk drives have been strongly demanded for loading in portable equipment such as a notebook computer.

In order to obtain thinner optical disk drives, it is important to reduce the thicknesses of optical pickup devices. For this purpose, optical pickup devices are expected to be reduced in thickness by reexamining the configurations of the main constituent components in the optical designs and structural designs of the optical pickup devices while keeping the performance and functions of the main constituent components.

The main constituent components of an optical pickup device include, for example, a semiconductor laser and a light receiving element for detecting a signal. By reducing the thickness of a semiconductor device including these main constituent components, the thickness of the optical pickup device can be reduced.

Referring to FIGS. 9A, 9B and 10, the following will describe a structural example of a representative semiconductor device and a structural example of an optical pickup according to the prior art.

FIGS. 9A and 9B are schematic diagrams illustrating the configuration of the semiconductor device according to the prior art. FIG. 10 is a schematic diagram illustrating a structural example of the optical pickup device according to the prior art.

In FIG. 9A, a semiconductor device 1 is made up of a semiconductor element 2, a stem 4, a cap 5, a glass 6 through which a laser beam 18 outputted from the semiconductor element 2 passes, a pair of lead terminals 7, wires 8 for connecting the electrodes of the anode and cathode of the semiconductor element 2 to the lead terminals 7, and a low-melting glass 9 for fixing the lead terminals 7 in through holes formed in the stem 4.

In a method of manufacturing the semiconductor device 1 of FIG. 9A, the lead terminals 7 are first fixed in the stem 4 with the low-melting glass 9. The lead terminals 7 are electrically connected to the semiconductor element 2 and are drawn to the outside of a package. Next, the semiconductor element 2 is bonded to the stem 4, and the electrodes of the anode and cathode of the semiconductor element 2 are connected to the pair of lead terminals 7 via the wires 8. After that, the glass 6 is fixed on the window of the end face of the cap with a low-melting glass, and the cap 5 is finally fixed and sealed on the flat surface of the stem 4 by hermetic welding. Thus it is possible to realize hermetic sealing by which the semiconductor device 1 is filled with mixed gases.

FIG. 10 is a schematic diagram illustrating an optical pickup of the prior art in which the semiconductor device 1 is mounted.

In FIG. 10, the semiconductor device 1 is mounted in a body 13 of an optical pickup device 12. In this configuration, the semiconductor device 1 and an optical disk 14 are optically coupled to each other via an optical component 15 which is a collimate lens, a rising mirror 16, and an objective lens 17. In other words, a laser beam 18 emitted from the semiconductor laser (not shown) of the semiconductor device 1 in FIG. 10 is collimated into a parallel light beam through the optical component 15, the optical path of the laser beam is bent by 90° with the rising mirror 16, and then the objective lens 17 brings the light beam into focus on a pit recorded on the optical disk 14. The laser beam 18 having read a signal on the pit is reflected on the optical disk 14 and passes through the same path in the opposite direction. At this point, the laser beam 18 is split by a diffractive optical component 19 disposed between the optical component 15 and the rising mirror 16, is condensed by the optical component, and is applied to a light receiving element (not shown), so that the signal recorded on the optical disk 14 is read.

In order to reduce the thickness of the optical pickup device 12 configured thus, the outside dimension 11 of the semiconductor device 1 is preferably reduced. In other words, by reducing the outside dimension 11 of the semiconductor device 1, an optical disk drive can be reduced in thickness.

However, in order to perform hermetic sealing between the stem 4 and the cap 5 in the configuration of the semiconductor device 1 according to the prior art, the stem 4 has to have an area for flat contact with the end of the cap 5. When considering a dimensional tolerance, the minimum outside dimension 11 of the semiconductor device is limited, so that it is difficult to reduce the thickness of the optical pickup device 12 using the semiconductor device 1.

In order to address this problem, as shown in FIG. 9B, the outside dimension 11 is reduced by eliminating a hermetic welding configuration.

In a method of manufacturing a semiconductor device 1 of FIG. 9B, lead terminals 7 are first fixed in a stem 4, which has been formed by drawing a thin metal plate, with an insulator such as a low-melting glass 9. Next, a semiconductor element 2 and a sub mount 3 are bonded to the stem 4, and the electrodes of the anode and cathode of the semiconductor element 2 are connected to the pair of lead terminals 7 via wires 8. After that, the stem 4 is brought into contact with a cap 5 and is inserted into the cap 5 having a glass 6 fixed on the window of the end face of the cap 5 with a low-melting glass, so that the stem 4 is press-fitted according to a dimensional tolerance between the outside shape of the stem 4 and the inside diameter of the cap 5. Thus hermetic sealing is completed. This configuration makes it possible to eliminate a flat part for hermetic sealing in the outside dimension 11 of the semiconductor device, achieving further size reduction as compared with the configuration of FIG. 9A.

### DISCLOSURE OF THE INVENTION

However, in response to size reduction of portable equipment such as a notebook computer, further reduction in thickness has been demanded of semiconductor devices as well as mounted optical disk drives. Further, higher powers are necessary for enhanced speed in recording, and semiconductor devices cannot be reliable without heat dissipation.

In response to this demand the stem 4 of the semiconductor device shown in FIG. 9B is formed by drawing, so that the size reduction of the semiconductor device is limited. The dimensional accuracy of processing on the mounting surface of the semiconductor element 2 may decrease and adversely affect the performance of the semiconductor device. To be specific, it is difficult to configure the semiconductor device of FIG. 9B when the outside dimension 11 is not larger than 2 mm. Further, in view of heat dissipation, the mounting surface of the stem 4 on which the semiconductor element 2 and the sub mount 3 are mounted is configured on the ends of the thin-plate components having been formed by drawing, and only a circular part formed at the base of the stem 4 is in contact with the inner surface of the cap 5 which dissipates heat to the outside, so that a large contact area with the cap 5 cannot be obtained and a thin heat dissipation path from the mounting surface of the semiconductor element 2 results in a small thermal capacity. Consequently, sufficient heat dissipation is hard to obtain.

The present invention has been devised to solve the problems of the prior art. An object of the present invention is to achieve high heat dissipation and reduce the thickness of a semiconductor device.

In order to attain the object, a semiconductor device of the present invention includes: a stem having a body and a mounting part for a semiconductor element; a wiring member electrically connected to the semiconductor element as an external terminal; a slit formed on the stem to fit and hold the wiring member; a cap which covers, in contact with the body, the stem having the wiring member held therein and the semiconductor element mounted thereon, and has an opening for exposing the external terminal portion of the wiring member; and a sealant provided on the opening to hermetically seal the stem into the cap, wherein the body has an inside dimension substantially equal to the minimum width of the mounting surface of the semiconductor element.

Further, a semiconductor device of the present invention includes: a stem having a body and a mounting part for a semiconductor laser; a wiring member electrically connected to the semiconductor laser as an external terminal; a slit formed on the stem to fit and hold the wiring member; a cap which covers, in contact with the body, the stem having the wiring member held therein and the semiconductor laser mounted thereon, and has an opening for exposing the external terminal portion of the wiring member; a through hole provided on a surface of the cap so as to be opposed to the opening of the cap; a transparent member provided on the through hole; and a sealant provided on the opening to hermetically seal the stem into the cap, wherein the body has an inside dimension substantially equal to the minimum width of the mounting surface of the semiconductor laser.

Moreover, the body is cylindrical, the mounting part is provided by forming a flat surface on a part of the cylindrical body, a cylindrical part of the body is in contact with the cap, and the cylindrical part has a circular cross section substantially equal in diameter to the minimum width of the mounting surface of the semiconductor laser.

Further, the semiconductor device includes an optical component on the through hole of the cap.

Moreover, the semiconductor laser is a nitride semiconductor laser.

Further, the semiconductor device includes a light receiving element.

Moreover, the semiconductor device includes a cut surface on a side of the stem.

Further, the semiconductor device includes a flange formed on the end of the opening of the cap, wherein at least one side of the flange is cut to form a linear portion.

A method of manufacturing the semiconductor device according to the present invention, in the manufacturing of the semiconductor device, the method including the steps of: bonding the semiconductor laser on the mounting part of the stem; connecting the semiconductor laser and flexible wiring; and subsequently fixing the stem and the cap, wherein the step of fixing the stem and the cap is performed by press fitting and hermetic sealing using the sealant.

### BRIEF DESCRIPTION OF THE DRAWINGS

FIG. 1A illustrates the configuration of a semiconductor device according to a first embodiment;

FIG. 1B illustrates the configuration of the semiconductor device according to the first embodiment;

FIG. 1C illustrates the configuration of the semiconductor device according to the first embodiment;

FIG. 2A illustrates the configuration of the semiconductor device in which flexible wiring is bent;

FIG. 2B illustrates the configuration of the semiconductor device in which the flexible wiring is bent;

FIG. 3A illustrates the configuration of the semiconductor device including a light receiving element;

FIG. 3B illustrates the configuration of the semiconductor device including the light receiving element;

FIG. 4 is a sectional view showing a cylindrical part of a stem and the shape of a slit formed on the cylindrical part;

FIG. 5 is a perspective view showing a method of manufacturing the semiconductor device and production equipment according to a second embodiment;

FIG. 6 is a sectional view showing the method of manufacturing the semiconductor device and the production equipment according to the second embodiment;

FIG. 7 is a schematic diagram showing an optical pickup device according to a third embodiment;

FIG. 8 is a schematic structural diagram showing an optical disk drive using the optical pickup of the present invention;

FIG. 9A is a schematic diagram illustrating the configuration of a semiconductor device according to the prior art;

FIG. 9B is a schematic diagram illustrating the configuration of a semiconductor device according to the prior art; and

FIG. 10 is a schematic diagram illustrating a structural example of an optical pickup device according to the prior art.

### DESCRIPTION OF THE EMBODIMENTS

Semiconductor devices according to embodiments of the present invention will now be described with reference to the accompanying drawings. The explanation of constituent elements indicated by the same reference numerals may be omitted.

### First Embodiment

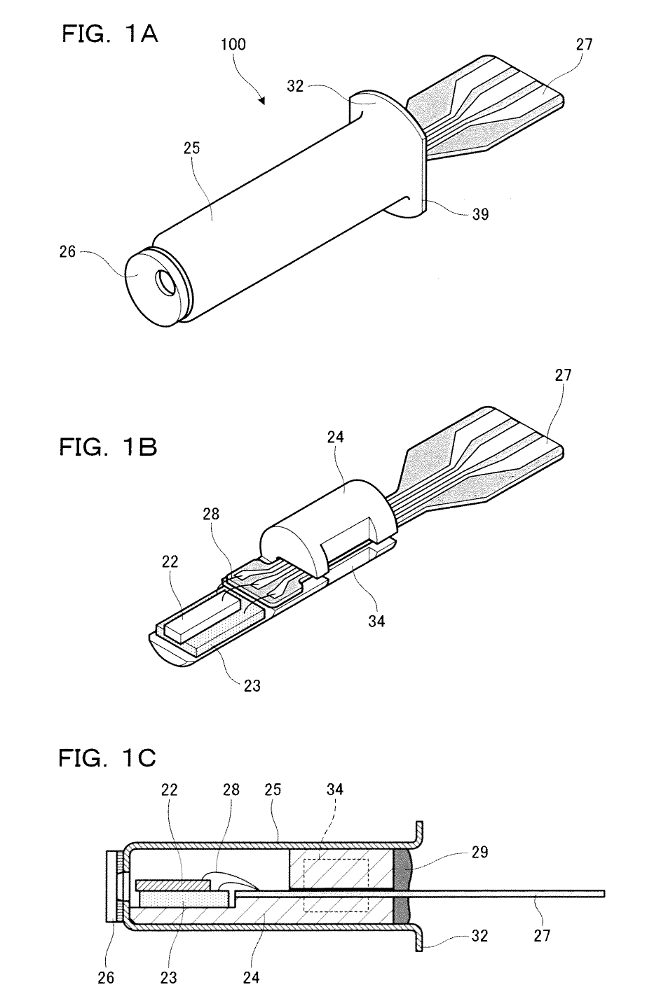

FIGS. 1A, 1B, 1C, 2A, 2B, 3A, 3B, and 4 show an embodiment of the present invention.

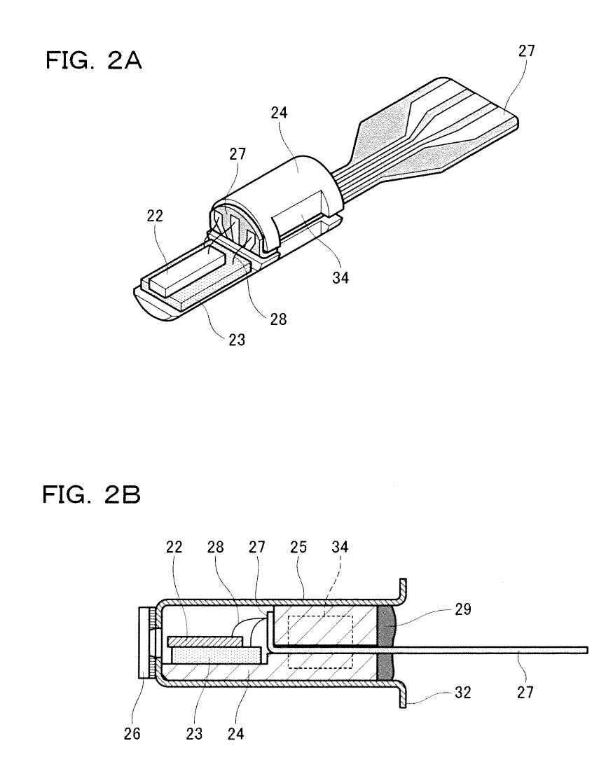

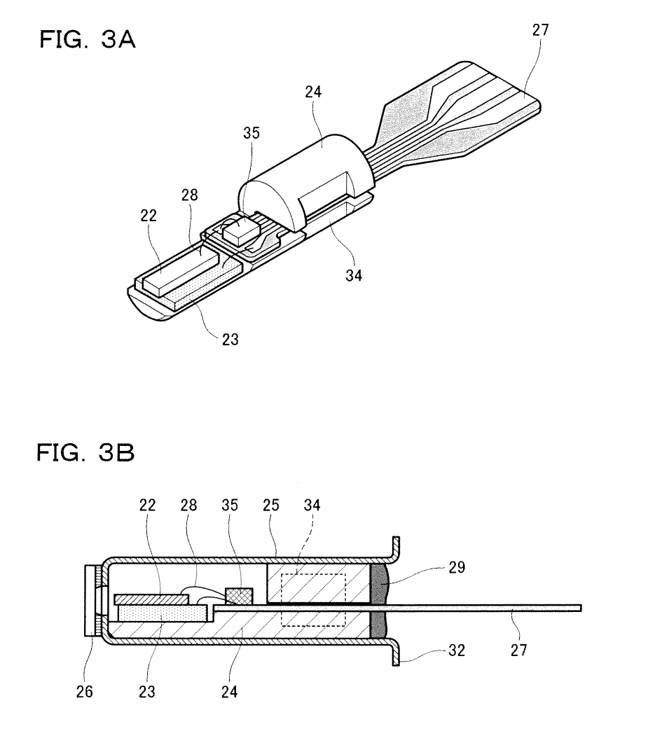

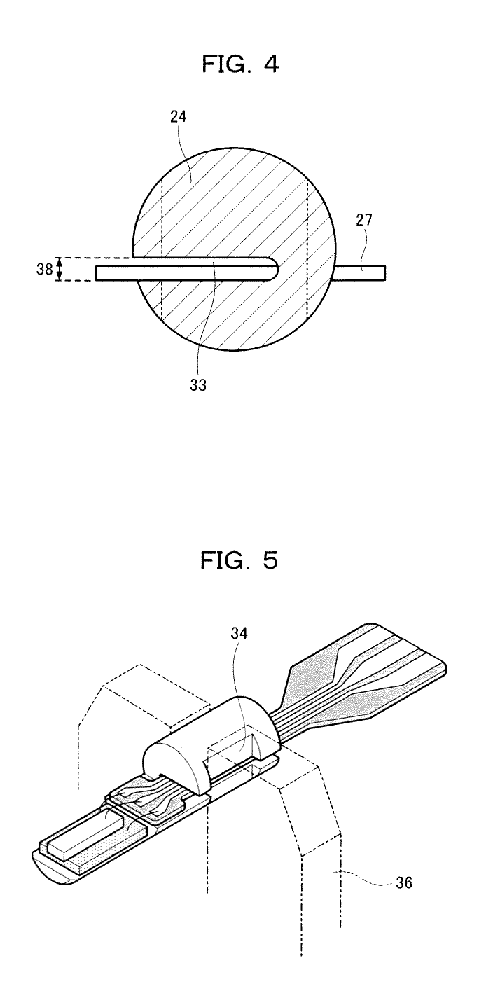

FIGS. 1A, 1B, and 1C show the configuration of a semiconductor device according to a first embodiment. FIG. 1A is a perspective view showing the semiconductor device according to the first embodiment of the present invention. FIG. 1B is a perspective view showing the configuration of the semiconductor device before the cap of the semiconductor device is installed according to the first embodiment. FIG. 1C is a sectional view showing the semiconductor device according to the first embodiment. FIGS. 2A and 2B show the configuration of the semiconductor device in which flexible wiring is bent. FIG. 2A is a perspective view and FIG. 2B is a sectional view. FIGS. 3A and 3B show the configuration of the semiconductor device including a light receiving element. FIG. 3A is a perspective view and FIG. 3B is a sectional view. FIG. 4 is a sectional view showing a cylindrical part of a stem and the shape of a slit formed on the cylindrical part.

In FIGS. 1A, 1B, and 1C, a semiconductor device 100 of the present invention is made up of a semiconductor element 22, a sub mount 23 of the semiconductor element 22, a stem 24, a cap 25 having a through hole for passing a laser beam outputted from the semiconductor element 22, a glass 26 fixed on the through hole, flexible wiring 27, wires 28 for connecting the electrodes of the anode and cathode of the semiconductor element 22 and the flexible wiring 27, and a sealant 29 for sealing and fixing the stem 24 after the stem 24 is press-fitted and assembled into the cap 25. Although the glass 26 is used in this configuration, a transparent member allowing the passage of a laser beam may be used. Further, instead of the flexible wiring 27, a substrate on which wires are provided and the ends of the wires act as terminals may be used or a wiring member such as a lead frame may be used.

The stem 24 is made up of a cylindrical material and has a mounting surface and a cylindrical part. The mounting surface fixes the semiconductor element 22, the sub mount 23, and the internal wiring of the flexible wiring 27 for electrically connecting the semiconductor element 22 to the outside. The mounting surface for mounting these members is formed by cutting a part of the cylindrical material along the length of a cylinder. The sub mount 23 is mounted on the base of the stem 24 with a solder material such that the laser beam emitting surface of the semiconductor element 22 mounted on the sub mount 23 is directed opposite to the layout of the flexible wiring on the stem 24. In this mounting step, the frame of the stem 24 and lead wiring terminals are not present in all directions along the flat surface of the semiconductor element 22. Thus a collet for sucking the semiconductor element 22 and the stem 24 do not interfere with each other. It is therefore possible to minimize the dimensions of the mounting surface of the semiconductor element, that is, the mounting surface of the stem 24 for the semiconductor element 22 or the sub mount 23 relative to the outside dimension of the semiconductor element 22 or the sub mount 23, thereby minimizing the outside dimensions of the cap 25. To be specific, the mounting surface only has to be as large as the sum of a mounting error and the outside dimension of the semiconductor element 22 or the sub mount 23, only has to be so large as to prevent the thickness of the semiconductor element 22 or the sub mount 23 from causing interference with the cap 25, or only has to have the minimum region for mounting the semiconductor element without consideration of the interference and so on of the collet. Moreover, by forming the mounting surface on a cross section including the diameter of the cylinder, the diameter of the cylinder and the dimensions of the stem are minimized, thereby reducing the thickness of the semiconductor device. To be specific, the diameter of the circular cross section of the cylinder is made substantially equal to the minimum width of the mounting surface, and the width of the mounting surface is made equal to the diameter of the circular cross section, so that the stem can be configured with the outside dimension of +800 μm relative to the dimension of the sub mount in a direction perpendicular to the direction of laser beam emission from the semiconductor element 22.

These dimensions are not larger than a half of the thickness and width of the semiconductor device of the prior art. Thus it is possible to fabricate a semiconductor device having a thickness of not larger than 2 mm when mounted.

The configuration of the present embodiment can reduce the thickness of the semiconductor device, achieving a semiconductor device with a smaller thickness.

Further, the stem is completely included in the cap and is in contact with the cap in the cylindrical part, so that a large contact area can be obtained between the stem and the cap. Thus heat generated from the semiconductor element can be dissipated from the overall cap, so that the heat dissipation improves.

The flexible wiring 27 is, as shown in FIG. 4, fixed so as to be inserted into a slit having a certain width 38 on the stem cylindrical part. The width 38 may be minimized according to the thickness of the used flexible wiring 27. A clearance made after the flexible wiring 27 is set is sealed in a sealing step, which will be described later, so that airtightness can be obtained.

In the semiconductor device 100 of the present invention, the electrodes of the anode and cathode of the semiconductor element 22 are connected to the flexible wiring 27 via the wires 28, the stem 24 is inserted into the cap 25, and the sealant 29 is applied and injected into the opening of the cap, so that the stem 24 is sealed and fixed. Any sealant may be selected according to the mounted semiconductor element 22. By using low-melting solder which is a representative example of the sealant, even when the semiconductor element 22 is a nitride semiconductor laser, a laser beam emitted from the nitride semiconductor laser reacts chemically with an organic compound and the compound is deposited on the emission end face of the nitride semiconductor laser, so that a reliable semiconductor device can be achieved without degrading the characteristics and reliability of the nitride semiconductor laser. In the case of other semiconductor elements, a resin adhesive with higher productivity can be used.

As shown in FIGS. 2A and 2B, the semiconductor device of the present invention may be configured such that the flexible wiring 27 on the side of the inner wiring of the stem 24 is fixed after being bent perpendicularly to the mounting surface of the semiconductor element 22. This configuration can eliminate the necessity for a space for laying out the inner wiring of the flexible wiring 27 on the plane and reduce the dimension of the semiconductor device along the length of the semiconductor device by about 1 mm. In this case, the wires 28 for connecting the semiconductor element 22, the sub mount 23, and the flexible wiring 27 have to be perpendicularly bonded. Such bonding can be performed by existing equipment without any problems.

Regarding a rewritable optical disk, it is important to control the optical output of a high-power semiconductor laser. When the optical output excessively increases, information recorded on the optical disk is deleted or a large load may be applied to the semiconductor laser and affect the reliability. When the optical output is smaller than a predetermined output, previously recorded contents are insufficiently deleted in further recording on the optical disk, resulting in imperfect recording. Further, recorded information may not be correctly read. Thus it is quite important to keep constant and correctly control the optical output of a high-power semiconductor laser. For this purpose, generally, a laser beam emitted from a high-power semiconductor laser to an optical disk is partly detected and the current value of a laser source is controlled based on a detected value to keep constant an optical output.

FIGS. 3A and 3B show a light receiving element 35 for monitoring an optical output. The light receiving element 35 is mounted on the flexible wiring to detect a part of the optical output of a high-power semiconductor laser. The light receiving element 35 for monitoring an optical output is formed at the rear of the rear end face of the semiconductor element 22, so that a part of a laser beam (not shown) emitted from the rear end face of the semiconductor element 22 is received, the optical output of the overall laser beam is estimated, and a current value for driving the laser beam can be controlled so as to correctly keep a desired optical output. Thus a constant output laser beam is more stably outputted from the semiconductor device.

As shown in FIG. 1A, a flange 32 is provided on the end of the cap and is partly cut, and a cut portion 39 is provided on one side or both sides of the flange 32, so that the cap 25 can be correctly held and the semiconductor device 100, which is a finished product, can be precisely positioned when assembled into an optical pickup device. Consequently, for example, the mounting accuracy of the semiconductor device is improved. Also in the manufacturing of the optical pickup device, since the mounting accuracy of the semiconductor device is improved, a yield increases in the manufacturing of the semiconductor device and the optical pickup device.

In the present embodiment, the stem 24 is a metallic stem. Other kinds of stem such as a resin stem may be used and the material and shape of the stem 24 are not limited as long as the stem 24 can be used for an optical device. The stem 24 may come in shapes other than a cylinder and include a body and a mounting part.

Further, in the present embodiment, the semiconductor element is a semiconductor laser element. Semiconductor devices in which other semiconductor elements are mounted may be configured as the present embodiment.

### Second Embodiment

Referring to FIGS. 1A, 1B, 1C, 5 and 6, the following will describe a method of manufacturing the semiconductor device and production equipment according to the present invention.

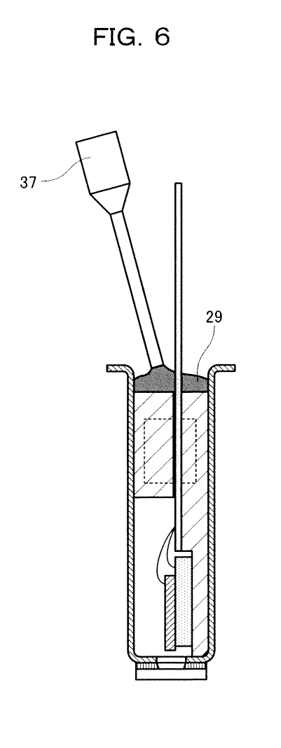

FIG. 5 is a perspective view showing the method of manufacturing the semiconductor device and the production equipment according to a second embodiment. FIG. 6 is a sectional view showing the method of manufacturing the semiconductor device and the production equipment according to the second embodiment.

FIG. 5 shows a mechanism for precisely holding and fixing the stem 24 with an adjusting claw 36 in the method of manufacturing the semiconductor device and the production equipment according to the present invention. Since the adjusting claw 36 holds cut surfaces 34 provided on the stem 24, positioning can be precisely performed when the semiconductor element 22 and the sub mount 23 are mounted and fixed and the wires 28 are connected to the semiconductor element 22 and the sub mount 23.

FIG. 6 shows a manufacturing method of applying and injecting a sealant after the stem 24 is inserted into the cap 25. The opening of the cap 25 is placed faceup and the sealant is applied by, for example, a dispenser and the like and is injected into the slit width 38 and around the stem 24. Sealing is completed when the sealant is fixed. At this point, air or adjusted gases are left in the cap 25 where the semiconductor element 22 is mounted, and thus the sealant does not excessively flow into the cap 25 from the slit width 38.

The manufacturing method and the production equipment of the present embodiment make it possible to easily obtain a small thickness and hermetic sealing in the semiconductor device of the first embodiment.

### Third Embodiment

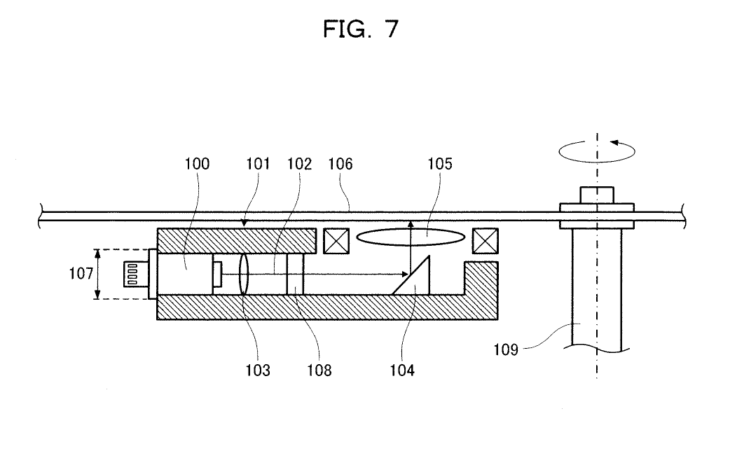

FIG. 7 is a schematic diagram showing an optical pickup device according to a third embodiment. The schematic diagram shows an optical pickup 101 including the semiconductor device of the first embodiment.

In FIG. 7, a laser beam 102 emitted from a semiconductor laser chip (not shown) of a semiconductor device 100 is collimated into a parallel light beam through an optical component 103 such as a collimate lens, the optical path of the light beam is bent by 90° with a rising mirror 104, and then an objective lens 105 brings the light beam into focus on a pit recorded on an optical disk 106. The laser beam 102 having read a signal on the pit is reflected on the optical disk 106, passes through the same path in the opposite direction, and returns to the semiconductor device 100. At this point, the laser beam 102 is split by a diffractive optical component 108 disposed between the optical component 103 and the rising mirror 104, is condensed by the optical component 103, and is applied to a light receiving element (not shown), so that the signal recorded on the optical disk is read. The optical disk 106 is rotated about a rotating shaft 109 which is rotated by a spindle motor.

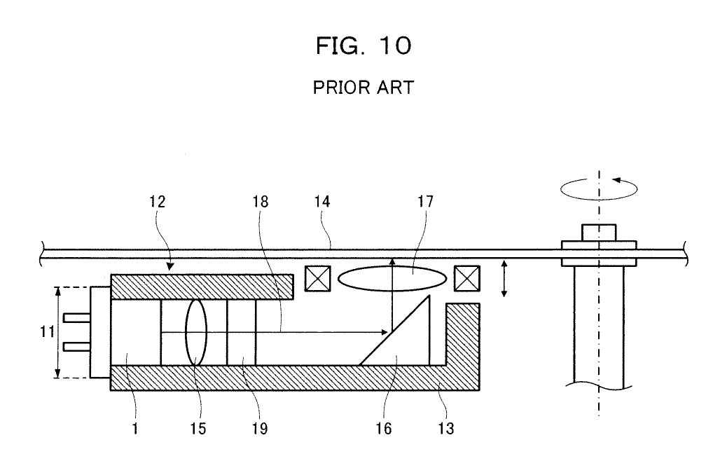

The thickness of the optical pickup device 101 configured thus is determined by a width 107 of the semiconductor device 100. In the present embodiment, the thickness of the optical pickup device 101 is 80% as large as the thickness of the optical pickup device 12 of the prior art shown in FIG. 10.

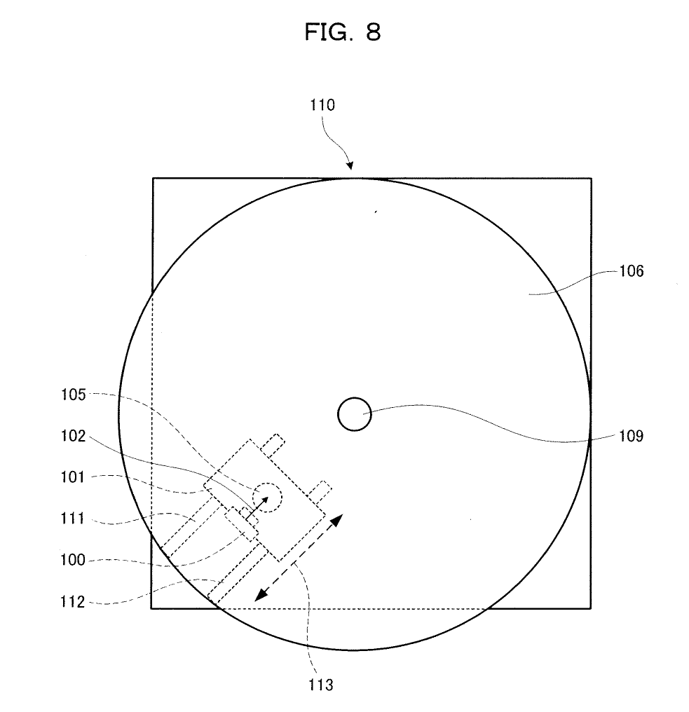

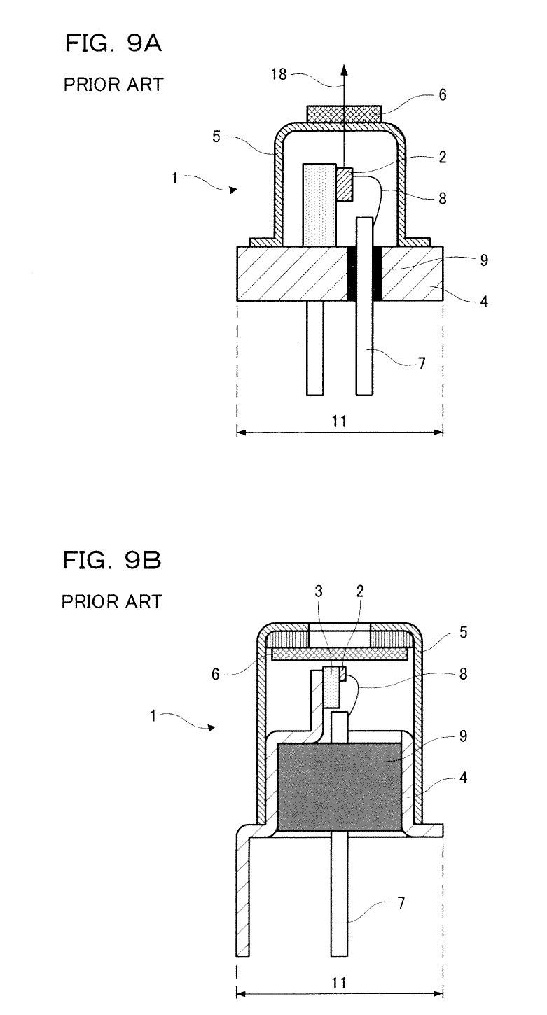

FIG. 8 is a schematic structural diagram showing an optical disk drive of the present invention. The structural diagram shows an optical disk drive unit (hereinafter, will be referred to as an optical disk drive) 110 using the optical pickup device 101 according to the present embodiment.

In FIG. 8, the optical disk drive 110 drives the rotating shaft 109 by means of a drive mechanism for rotating the optical disk 106. For recording and reproduction of a signal on the optical disk 106, the optical pickup device 101 shifts a moving direction 113 by means of supporting shafts 111 and 112 of a traverse mechanism which can move in the radial direction of the disk. Since the semiconductor device 100 having been reduced in thickness according to the present invention is mounted in the optical pickup device 101, the optical pickup device 101 is also reduced in thickness as shown in FIG. 7.

In the present embodiment, a semiconductor laser may be a multi-wavelength laser such as a dual-wavelength laser and a three-wavelength laser.

What is claimed is:

1. A semiconductor device, comprising:
a stem having a body and a mounting part for a semiconductor element;
a wiring member electrically connected to the semiconductor element as an external terminal;
a slit formed on the stem to fit and hold the wiring member;
a cap which covers, in contact with the body, the stem having the wiring member held therein and the semiconductor element mounted thereon, and has an opening for exposing an external terminal portion of the wiring member; and
a sealant provided on the opening to hermetically seal the stem into the cap,
wherein the body has an inside dimension substantially equal to a minimum width of a mounting surface of the semiconductor element.

2. The semiconductor device according to claim 1, wherein the body is cylindrical, the mounting part is provided by forming a flat surface on a part of the cylindrical body, a cylindrical part of the body is in contact with the cap, and the cylindrical part has a circular cross section substantially equal in diameter to the minimum width of the mounting surface of the semiconductor element.

3. A semiconductor device, comprising:
a stem having a body and a mounting part for a semiconductor laser;
a wiring member electrically connected to the semiconductor laser as an external terminal;
a slit formed on the stem to fit and hold the wiring member;
a cap which covers, in contact with the body, the stem having the wiring member held therein and the semiconductor laser mounted thereon, and has an opening for exposing an external terminal portion of the wiring member;
a through hole provided on a surface of the cap so as to be opposed to the opening of the cap;
a transparent member provided on the through hole; and
a sealant provided on the opening to hermetically seal the stem into the cap,
wherein the body has an inside dimension substantially equal to a minimum width of a mounting surface of the semiconductor laser.

4. The semiconductor device according to claim 3, wherein the body is cylindrical, the mounting part is provided by forming a flat surface on a part of the cylindrical body, a cylindrical part of the body is in contact with the cap, and the cylindrical part has a circular cross section substantially equal in diameter to the minimum width of the mounting surface of the semiconductor laser.

5. The semiconductor device according to claim 3, further comprising an optical component on the through hole of the cap.

6. The semiconductor device according to claim 4, further comprising an optical component on the through hole of the cap.

7. The semiconductor device according to claim 3, wherein the semiconductor laser is a nitride semiconductor laser.

8. The semiconductor device according to claim 4, wherein the semiconductor laser is a nitride semiconductor laser.

9. The semiconductor device according to claim 3, further comprising a light receiving element.

10. The semiconductor device according to claim 4, further comprising a light receiving element.

11. The semiconductor device according to claim 2, further comprising a cut surface on a side of the stem.

12. The semiconductor device according to claim 4, further comprising a cut surface on a side of the stem.

13. The semiconductor device according to claim 2, further comprising a flange formed on an end of the opening of the cap,
wherein at least one side of the flange is cut to form a linear portion.

14. The semiconductor device according to claim 4, further comprising a flange formed on an end of the opening of the cap,
wherein at least one side of the flange is cut to form a linear portion.

15. A method of manufacturing a semiconductor device, in manufacturing of the semiconductor device according to claim 4, the method comprising the steps of:
bonding the semiconductor laser on the mounting part of the stem;
connecting the semiconductor laser and flexible wiring; and
subsequently fixing the stem and the cap,
wherein the step of fixing the stem and the cap is performed by press fitting and hermetic sealing using the sealant.
